(19) United States
(12) Patent Application Publication
(10) Pub. No.: US 2025/0208187 A1
(43) Pub. Date: Jun. 26, 2025

(54) Control system of inputs/outputs of at least one avionic application and operation verification method of such a system

(71) Applicant: THALES, Meudon (FR)

(72) Inventors: Jean-Christophe RECULEAU, MERIGNAC (FR); Frédéric CAUDOUX, MERIGNAC (FR)

(21) Appl. No.: 18/985,408

(22) Filed: Dec. 18, 2024

(30) Foreign Application Priority Data
Dec. 22, 2023 (FR) 2315099

(51) Int. Cl. G01R 31/00; B64F 5/60

(52) U.S. Cl. CPC G01R 31/008; B64F 5/60

(57) ABSTRACT

An input/output control system for at least one avionics application including at least two computing platforms implemented using similar hardware and software resources, each platform including a primary stage configured to acquire analogue signals, an intermediate stage configured to digitally process digital signals, a final stage configured to make digital data available to the avionics application, a hardware monitoring module configured to implement an operating test by injecting predetermined test signals into the primary stage, and a software monitoring module configured to acquire digital data corresponding to the injected test signals, and to check that they correspond to predetermined values.

### REFERENCE TO RELATED APPLICATION

This application is a U.S. non-provisional application claiming the benefit of French Patent Application No. 23 15099 filed on Dec. 22, 2023, the contents of which are incorporated herein by reference in their entirety.

### TECHNICAL FIELD OF THE INVENTION

The present invention relates to an input/output control system for at least one avionics application.

The present invention also relates to a method of verifying the operation of such a system.

The field of the invention is that of on-board avionics in an aircraft.

### BACKGROUND OF THE INVENTION

As is well known, there are several levels of criticality in this field, depending on the functions implemented by the avionics. Criticality is considered from both an integrity and an availability point of view.

Generally speaking, flight control systems are among the most critical on an aircraft. These systems are generally responsible for:
acquiring the inertial and dynamic state of the aircraft;
acquiring the positions of surfaces and/or the state of the aircraft's engines; and
creating new surface position and/or motor status setpoints according to a setpoint trajectory to be followed.

As a result, it is easy to see that an erroneous setpoint, which would not be detected, for a given surface could lead to an irrecoverable imbalance in the aircraft.

A high-integrity system is one in which the probability of generating an undetected error is extremely low.

To date, there are two main techniques for obtaining a highly integrated system, using a command/supervision (or COMmand/MONitor or COM/MON) distribution to ensure that an isolated malfunction cannot generate an undetected error.

The first technique consists of using two dissimilar computing platforms in terms of both hardware and software, and making comparisons at application level between two independent applications known as COMmand and MONitor on the inputs consumed. In this way, producing a consistent error on the same functional input at the platform terminals is considered very unlikely. It would take a hardware failure with the same effect or a simultaneous and consistent hardware or software error on both dissimilar computing platforms to somehow fool the MONitor application, which compares its own calculations with those performed by the COMmand application. If a calculation discrepancy is detected between the two applications, a mechanism is used to inhibit the outputs calculated by the COMmand part.

The second technique involves using two partially dissimilar computing platforms. In particular, the hardware resources of these platforms are identical, but their basic software is different. In this case, the analysis or demonstration of the absence of a common fault or error only concerns the hardware perimeter. This principle is also based on the comparison by the MONitor channel of commands calculated by the COMmand channel.

However, both techniques have a number of disadvantages.

The first technique requires the development of two different types of platform, in terms of both hardware and basic software. It is therefore a source of costs not only for development, but also for industrialization (supply, lower volume effect) and maintenance.

The second technique is less restrictive than the first, but nevertheless requires the development of two dissimilar basic software packages with the associated maintenance costs.

It is therefore clear that each of these two techniques requires significant development, at least at software level, and therefore has significant development and maintenance costs.

### SUMMARY OF THE INVENTION

The aim of the present invention is to reduce the development, particularly software development, required to ensure the high integrity of a system. As a result, the invention reduces the associated cost.

To this end, the invention relates to an input/output control system for at least one avionics application configured to generate at least one integrated setpoint, the control system including at least two computation platforms implemented using similar hardware and software resources, one of the computation platforms forming a control chain and the other forming a monitoring chain, each computation platform including:
a primary stage configured to acquire analogue signals and convert them into digital signals;
an intermediate stage configured to digitally process the digital signals to form digital data;
a final stage configured to make digital data available to the avionics application;
a hardware monitoring module configured to implement an operating test of the primary, intermediate and final stages, by injecting predetermined test signals into the primary stage; and
a software monitoring module configured to acquire from the final stage digital data corresponding to the test signals injected by the hardware monitoring module into the primary stage, and to check that they correspond to predetermined values.

In other beneficial aspects of the invention, the system includes one or more of the following features, often taken in isolation or in any technically possible combination:
the predetermined test signals correspond to analogue signals, digital signals or discrete signals;
the software monitoring module is further configured to control the choice of test signals by the hardware monitoring module;
the software monitoring module is configured to check the correspondence of at least one of the following elements of the acquired digital data to predetermined values:
   authenticity;
   dating;
   integrity; and
   expected value.
the software monitoring and hardware monitoring modules are implemented using different technologies that are independent of those of the primary, intermediate and final stages;
the hardware monitoring module includes a function for monitoring the running of operating tests of the primary, intermediate and final stages, the software monitoring module being configured to periodically reactivate the monitoring function;
the primary stages of the different computing platforms are configured to be used asymmetrically;
the primary stage of each computing platform includes a connector, an analogue filter module and an input signal conversion module; and
the use of the primary stages of the different computing platforms in an asymmetric way includes at least one of the following elements:
   allocation of different connection points between different connectors;
   allocation of different routing paths and/or analogue filters between the different analogue filter modules; and
   asymmetrical use of different input signal conversion modules;
the intermediate stage of each computing platform includes a digital acquisition module, the digital acquisition modules of the different computing platforms being configured to be used asymmetrically;
the use of digital acquisition modules on different computing platforms in an asymmetric way includes a different sequencing between acquisitions on digital buses and analogue/digital conversions;
the intermediate stage of each computing platform includes a digital processing module configured to encapsulate each digital data item so as to be able to:
   use the platform's other modules to check the source of the data;
   use the platform's other modules to check the integrity of this data; and
   use the platform's other modules to check that the data is dated.
the intermediate stage is further configured to encapsulate each processed digital data item;
   each computing platform also including a verification application configured to verify the encapsulation of each item of data received;
encapsulating each digital datum includes forming an aggregate including that datum and at least one of the following:
   authentication means for authenticating the source of this data; and
   a means of dating the data and/or measuring its freshness;
the encapsulation of each digital data item further includes the formation of a digital signature of all or part of the corresponding aggregate;
the digital signature includes a CRC verification code;
the verification application is configured to verify at least one of the following elements of each data item received:
   the source of this data;
   the integrity of this data; and
   the dating of this data; and
the verification application is integrated into the final stage or the avionics application.

The invention also relates to a method of verifying the operation of a control system as defined above;

the checking method including the following operations:
injection of predetermined test signals into the primary stage;
acquisition from the final stage of the digital data corresponding to the test signals injected into the primary stage; and
checking that the digital data corresponds to predetermined values.

Alternatively or additionally, the invention relates to a method of checking the operation of a control system as defined above;
the method including the following operations:
   encapsulation of each digital data item processed by the intermediate stage; and
   verification of the encapsulation of each data item received by the verification application.

### BRIEF DESCRIPTION OF THE DRAWINGS

The invention will appear more clearly when reading the description that follows, given solely as a non-limiting example and made in reference to drawings in which:

FIG. 1 is a schematic view of a control system according to the invention, the control system including at least two computing platforms;

FIG. 2 is a schematic view of one of the computing platforms shown in FIG. 1; and

FIG. 3 is a flowchart of a verification process according to the invention, the verification process being implemented by the management system of FIG. 1.

### DETAILED DESCRIPTION OF THE INVENTION

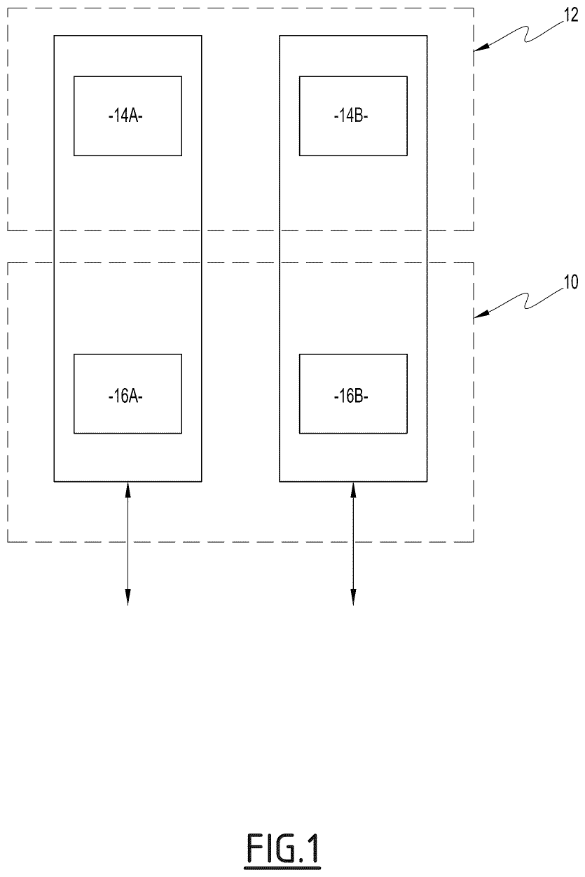

FIG. 1 shows an input/output control system 10 for at least one avionics application 12.

The avionics application 12 is configured to generate at least one integrated instruction intended for an avionics system, for example.

A “setpoint with integrity” is defined as a setpoint with a very low probability of being an undetected erroneous setpoint. This probability is, for example, less than 10-9 when both control and monitoring chains are considered, as will be explained below.

Advantageously, the setpoint integrity requirement applied to the avionics application 12 is also accompanied by a “No single failure” requirement. This last requirement requires the demonstration of the absence of a common mode between the two control and monitoring chains.

The avionics application 12 thus implements operation of a critical aircraft system, such as a flight control system.

By “aircraft” is meant any flying machine that may be controlled at least partially automatically and/or manually. In the latter case, the aircraft may be controlled by a pilot from a cockpit (for example, in the case of a plane or helicopter) or by a remote operator (for example, in the case of a drone).

As part of a highly integrated system, the avionics application 12 implements a control chain 14A, also known as the COM chain, and a monitoring chain 14B, also known as the MON chain.

The purpose of the monitoring chain 14B is to monitor operation of the control chain 14A, using techniques known per se. These techniques may, for example, include comparing the outputs of the two chains 14A, 14B and, where these outputs differ, treating such a case as a malfunction.

The control system 10 includes at least two computing platforms 16A, 16B.

In particular, the control system 10 includes a calculation platform 16A, 16B for each chain of the avionics application 12.

Each calculation platform 16A, 16B manages the inputs and/or outputs of the corresponding chain 14A, 14B of the application 12.

For example, each computing platform 16A, 16B is configured to receive data, for example in the form of analogue signals, and to convert and deliver this data to the corresponding chain 14A, 14B of the avionics software 12. Each computing platform 16A, 16B is further configured to receive digital data from the corresponding chain 14A, 14B of the avionics software 12, and to convert and deliver this data to any interested system, for example, in the form of analogue signals.

Similarly to the avionics application 12, one of these platforms 16A forms a control chain or simply a COM chain of the control system 10, and the other platform 16B forms a monitoring chain or simply a MON chain of the control system 10.

In the example shown in FIG. 1, the computing platform 16A forms the COM chain of the control system 10 and the computing platform 16B forms the MON chain of the control system 10. The calculation platform 16A is therefore associated with the control chain 14A of the avionics application 12, and the calculation platform 16B is associated with the monitoring chain 14B of the avionics application 12.

Other examples of the combination of processing chains, their number and the way they interact are also possible.

Each computing platform 16A, 16B is defined by an identifier. Such an identifier may, for example, have a physical digital identifier with a signature. The identifiers of different computing platforms 16A, 16B are exchanged, for example, when the system 10 is started up to check consistency.

According to the invention, the computing platforms 16A, 16B are implemented using similar hardware and software resources.

“Similar hardware and software resources” means resources implemented using the same technology, in particular as regards their production, composition, programming languages, operating algorithm, etc.

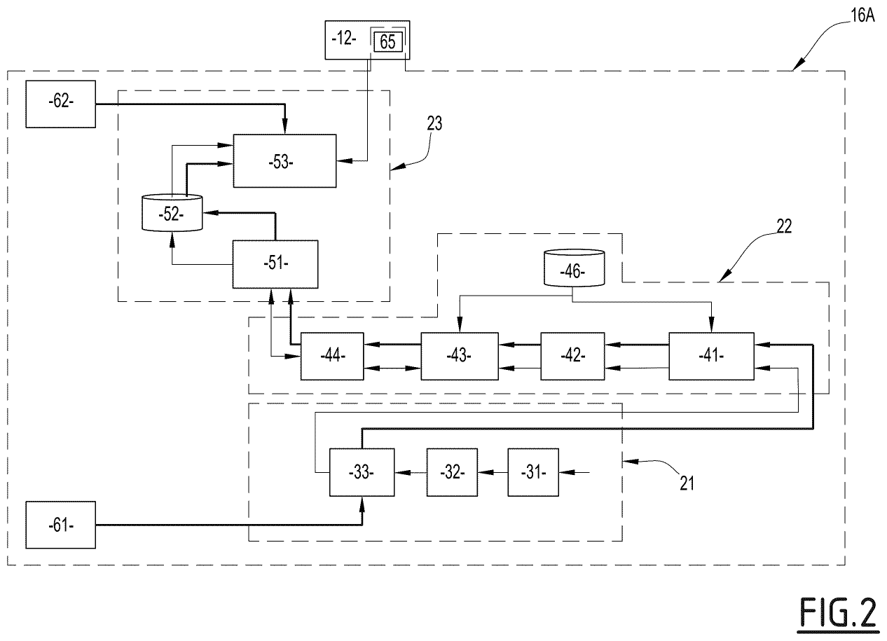

The calculation platforms 16A and 16B are therefore similar. Hereafter, only one platform, for example platform 16A, will be explained in more detail with reference to FIG. 2.

Thus, as illustrated in FIG. 2, the computing platform 16 includes a primary stage 21 configured to acquire analogue signals and convert them into digital signals, an intermediate stage 22 configured to digitally process the digital signals to form digital data, and a final stage 23 configured to make the digital data available to the avionics application 12 and in particular to its corresponding chain 14A.

The composition of each of the stages 21 to 23 is described below with reference to FIG. 2. However, it must be understood that other examples of these floors are also possible.

The primary stage 21 includes a connector 31, an analogue filter module 32 and an input signal conversion module 33.

Connector 31 enables the platform 16A to be connected to any interested system producing/consuming data in the form of analogue signals. For example, such a system has one or more sensors (e.g., for position, pressure, speed, etc.) or one or more controllable surfaces (e.g., surfaces used by flight controls).

To do this, the connector 31 has a plurality of connection points arranged, for example, on a physical medium in a predetermined format. Each of these connection points is then able to receive/send a sub-signal of a particular type. All the sub-signals transmitted/received then form the analogue signal transmitted/received by connector 31.

The analogue filter module 32 is used to apply analogue filtering to the analogue signals received. This filtering may include one or more successive filters. For example, such filtering can form elements of protection against environmental aggression: lightning strikes, electromagnetic disturbances in particular, etc.

The input signal conversion module 33 is used to convert received and possibly filtered analogue signals into digital signals or to format digital bus signals into signals that can be used by a digital core of the 16A platform. Analogue/digital converters and/or other means of formatting known per se may be used for this purpose. The input signal conversion module 33 is therefore able to receive digital signals via one or more digital buses and analogue signals via one or more analogue inputs.

The intermediate stage 22 includes a digital acquisition module 41, a digital processing module 42, a storage area 43 and a communication bus 44.

The digital acquisition module 41 is connected to the input signal conversion module 33 by one or more buses and is used to acquire the digital signals supplied by this conversion module 33. In particular, this module 41 enables three types of acquisition to be made:
acquisition of digital input data on the various digital buses; these may be legacy buses such as ARINC 429 or specific buses such as RS485 or Ethernet serial lines. In the latter case, the digital data arrives asynchronously and unsolicited by this module 41. To manage this asynchronism, the digital acquisition module 41 may perform a technique called “polling”. This technique is applied to all the buses to be controlled quickly enough to avoid data loss.
digital data acquisition corresponding to analogue/digital conversions. In this case, the acquisitions are controlled by the digital acquisition module 41, which manages the configuration, sequencing and acquisition of the conversion. In other words, in this case, acquisitions are made synchronously.
input discrete acquisitions including a function for confirming a change of state of an input discrete.

The digital processing module 42 is connected to the digital acquisition module 41 and is used to digitally process the digital data acquired by this digital acquisition module 41.

This processing may be chosen according to the digital data acquired and includes, for example:
for data from the conversion module 33, digital filtering processes to extract physical values that can be used by applications; these processes may consist of more or less complex filters to ensure, for example:
   signal conversion according to the type and level of precision expected;
   specific additional filtering to enable applications running at low frequencies to read values filtered accordingly; and
protocol control processing, typically for digital buses, which consists of extracting useful information from signals according to the protocol chosen for these buses.

The storage area 43 is used to store, at least temporarily, the digital data produced by the digital processing modules 42. In particular, after conversion, data corresponding to an input will usually be stored at a fixed address or in a data queue. The storage method is advantageously chosen as a function of the type of data (analogue/digital conversion, protocol data, etc.) and/or the mode of data acquisition by the basic software (direct access to inputs by the software, input/output software server, etc.).

The communication bus 44 is used to transmit this data to the final stage 23.

In particular, this communication bus represents the physical interface between the software and hardware parts of the platform 16A. Data acquisition by the software is therefore carried out via this interface.

Advantageously, the operation of the digital acquisition module 41 and the storage area 43 is controlled by a plurality of parameters. These parameters are stored, for example, in a database 46 which is also part of the intermediate stage 22.

The final stage 23 includes a logic decomposition which may be chosen differently depending on the implementation chosen to carry out the acquisitions by the software.

For example, in a “client-server” model, the final stage 23 includes an input acquisition process 51 which is asynchronous with the user and which acquires the data from the communication bus 44 and stores it in a buffer memory 52. The final stage 23 also includes a client service 53 enabling the avionics application 12 to acquire data asynchronously from the buffer memory 52.

In another embodiment, the elements 51, 52 and 53 may be seen as a single element constituting the final stage 23.

According to the invention, the computing platforms 16A, 16B implement at least one of the four mechanisms to render the inputs to the avionics application 12 provided by the control system 10 intact. It should be noted that each of these mechanisms may be implemented independently of the others.

According to a first mechanism, each of the computing platforms 16A, 16B also includes a hardware monitoring module 61 and a software monitoring module 62. These modules 61, 62 will be explained below with reference to the calculation platform 16A and in particular to FIG. 2.

The hardware monitoring module 61 is configured to implement a functional test of all the stages 21, 22, 23, by injecting predetermined test signals into the primary stage 21.

To do this, the hardware monitoring module 61 is connected to the primary stage 21 and in particular to the input signal conversion module 31, to inject the corresponding test signals into this module 31.

The predetermined test signals may be analogue signals, digital signals or discrete signals.

In particular, the test signals in the form of digital signals may include any type of digital data received on one or more buses reserved for input to the input signal conversion module 33. The test signals in the form of digital signals make it possible to cover all possible values on one or more digital buses to check the correct decoding of any value, in particular by the input signal conversion module 33 and correct processing by the digital processing module 42.

The test signals in the form of analogue signals may include any type of analogue data possible on one or more analogue inputs of the input signal conversion module 33. The test signals in the form of analogue signals enable all analogue values to be covered in order to check the different types of digital filtering implemented by the digital processing module 42.

The test signals in the form of discrete signals enable the digital acquisition module 41 to be tested and input discrete signals to be confirmed in this module.

The software monitoring module 62 is configured to acquire from the final stage 23 digital data corresponding to the test signals injected by the hardware monitoring module 61 into the primary stage 21, and to check that they correspond to predetermined values. In particular, these predetermined values are determined from the test signals injected by the module 61 and are stored, for example, in the software monitoring module 62.

Even more particularly, the software monitoring module 62 is configured to check at least one of the following elements of the acquired digital data:
authenticity;
dating;
integrity; and
expected value.

To acquire the corresponding digital data, the software monitoring module 62 is connected to the final stage 23 and in particular to the customer service 53 in the example shown in FIG. 2.

The software monitoring module 62 is also configured to control the choice of test signals by the hardware monitoring module 61.

The software monitoring module 62 and the hardware monitoring module 61 are implemented using different technologies that are independent of those of the primary stage 21, intermediate stage 22 and final stage 23.

In particular, the hardware monitoring module 61 is implemented in a digital component that is totally independent of each of the following elements:
the communication bus 44;
the digital processing module 42;
the storage area 43; and
the digital acquisition module 41.

The software monitoring module 62 is implemented in a software component that is independent of the software components of the final stage 23 and in particular of the input acquisition process 51 and the customer service 53.

Finally, the hardware monitoring module 61 includes a function for monitoring the execution of operating tests on the primary, intermediate and final stages 21, 22 and 23. The software monitoring module 62 is configured to periodically reactivate this monitoring function in order to test the operation of stages 21 to 23.

According to a second mechanism, the intermediate stage 22 of each of the computing platforms 16A, 16B encapsulates each digital data item acquired and processed respectively by the digital acquisition module 41 and the digital processing module 42. This encapsulation is done in such a way that at least one of the following elements may be verified:
the source of this data (i.e., the digital acquisition module 41 or the digital processing module 42);
the integrity of this data (in particular when it is transmitted between the digital processing module 42 and when it is received by an application); and
the dating of this data (for example, its freshness).

This verification is carried out, for example, by a verification application 65 integrated in the final stage 23 (for example, in the customer service 53) or in the avionics application 12, as shown in FIG. 2.

Each data item is encapsulated by the digital processing module 42, for example, by forming an aggregate including this data item (i.e., useful data) and at least one of the following elements:
authentication means for authenticating the source of this data; and
a means of dating the data and/or measuring its freshness.

The authentication means includes, for example, one or more data corresponding to an identifier of the entity that produced the corresponding data.

The dating means includes, for example, one or more data corresponding to the production date of the corresponding data.

The encapsulation of each piece of digital data may also include the formation of a digital signature for all or part of the aggregate including this data (for example, only the authentication means and/or the dating means). The digital signature may correspond to a CRC verification code and may be included in the aggregate to be transmitted with the data.

When each item of data is received, the verification application 65 is configured to check the origin, integrity and freshness of the data received. Integrity is verified using the digital signature.

The verification application 65 may also be configured to decapsulate the corresponding data. In other words, the verification application 65 may be further configured to extract the useful data from each corresponding aggregate and then transmit it to the corresponding application.

In particular, the second mechanism enables:
authenticating data on a digital bus after protocol decoding and adding a digital signature to this data to verify the complete integrity of the data at application level;
authenticating digital data resulting from digital filtering (conversion of analogue values) and adding a digital signature to this data to verify the complete integrity of the data at application level; and
ensuring that the data is not frozen and with consistent refresh times for the system 10.

This mechanism therefore makes it possible to cover an error that could be introduced by the storage area 43, the communication bus 44 and possibly by the input acquisition process 51, the buffer memory 52 and the client service 53.

According to a third mechanism, the primary stages 21 of the different computing platforms 16A, 16B are configured to be used asymmetrically.

In particular, such asymmetrical use includes at least one of the following:
allocation of different connection points between the different connectors 31;
allocation of different routing paths and/or analogue filters between the different analogue filter modules 32; and
asymmetrical use of different input signal conversion modules 33.

More specifically, this last element may include the asymmetrical use of the different buses/inputs used by these 33 modules.

Advantageously, the asymmetrical use of the primary stages 21 includes at least two of the aforementioned elements.

According to a fourth mechanism, the digital acquisition modules 41 of the different computing platforms 16A, 16B are configured to be used asymmetrically.

This asymmetry can be introduced into the sequencing of the acquisition of signals from the input signal conversion module 33 between the different computing platforms 16A, 16B. This sequencing consists, for example, of:
acquisition by the input signal conversion module 33 on the digital buses; and
to perform the analogue/digital conversions by the input signal conversion module 33.

This sequencing may be done in a different order in the different computing platforms 16A, 16B.

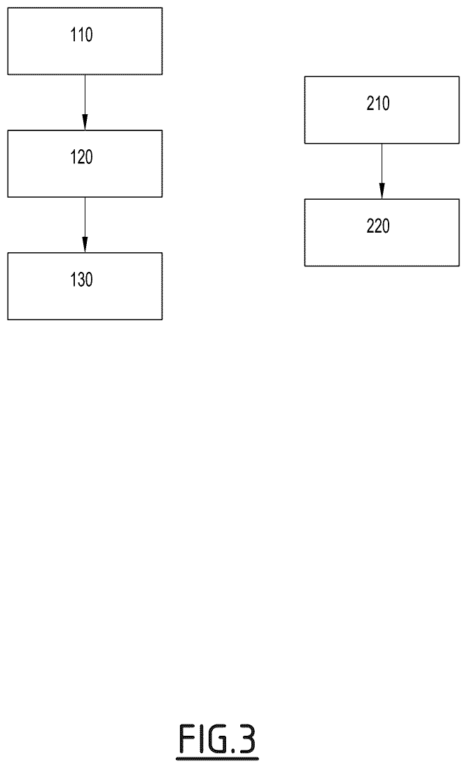

A method for checking the operation of the management system 10 will now be explained with reference to FIG. 3, which shows a flowchart of its stages.

This method includes operating the first mechanism and the second mechanism independently of each other. This means that only one of these two mechanisms may be implemented. It is also considered that the third mechanism and/or the fourth mechanism is/are implemented optionally during the running of this method.

In particular, implementation of the first mechanism includes operations 110 to 130 and implementation of the second mechanism includes operations 210 to 220, explained below.

In operation 110, the hardware monitoring module 61 injects predetermined test signals into the primary stage 21. As explained above, these signals may be selected by the software monitoring module 62.

In addition, depending on the nature of these signals, they may be injected via digital buses or analogue inputs of the input signal conversion module 33.

The injected signals then pass through the intermediate stage 22 and the final stage 23.

In the next operation 120, the software monitoring module 62 acquires the digital data corresponding to the test signals injected and then passed through the stages 22 and 23.

In the next operation 130, the software monitoring module 62 checks that these acquired digital data correspond to predetermined values.

In particular, as explained above, these predetermined values may verify the authenticity, dating, integrity and/or expected value of the acquired digital data.

During operation 210, the intermediate stage 22, and in particular the digital processing module 42, encapsulates each data item acquired by the digital acquisition module 41 and possibly processed by the module 42.

As explained above, this encapsulation includes in particular the addition of an authentication means and/or a dating means. Encapsulation may also include the addition of a digital signature.

The encapsulated data then passes through the rest of the intermediate stage 22 and the final stage 23.

In the next operation 220, the verification application 65 receives the encapsulated data and verifies its encapsulation. In particular, this verification may include checking the authenticity and/or freshness and/or integrity of this data.

Then, the verification application 65 may decapsulate the data (i.e., extract the useful data from the corresponding aggregate) before transmitting this data to the avionics application 12.

It is therefore clear this present invention has a number of advantages.

In particular, the control system according to the invention implements at least one of the aforementioned mechanisms for proving the integrity of each data item supplied to the avionics application. In some examples, the control system may implement at least two mechanisms or at least three mechanisms. In some examples, the control system uses all four mechanisms.

This means that the different computing platforms making up such a system can be implemented in a similar way in terms of hardware and software. This considerably reduces the cost of developing and maintaining such computing platforms.

Of course, other embodiments of the control system as claimed are also possible.

1. An input/output control system for at least one avionics application that generates at least one integrated setpoint, the control system comprising at least two computing platforms implemented using similar hardware and software resources, one of the computing platforms forming a control chain and another forming a monitoring chain, each computing platform comprising:
a primary stage acquiring analogue signals and converting them into digital signals;
an intermediate stage processing the digital signals to form digital data;
a final stage making the digital data available to the avionics application;
a hardware monitoring module implementing an operating test of said primary, intermediate and final stages, by injecting predetermined test signals into said primary stage; and
a software monitoring module acquiring, from said final stage, digital data corresponding to the test signals injected by said hardware monitoring module into said primary stage, and to verify their correspondence with predetermined values.

2. A system of claim 1, wherein the predetermined test signals correspond to analogue signals, digital signals or discrete signals.

3. A system of claim 1, wherein said software monitoring module is further configured to control the selection of test signals by said hardware monitoring module.

4. A system of claim 1, wherein said software monitoring module is configured to check the correspondence of at least one of the following elements of the acquired digital data to predetermined values:
authenticity;
dating;
integrity; and
expected value.

5. A system of claim 1, wherein said software monitoring and hardware monitoring modules are implemented according to different technologies independent of those of said primary, intermediate and final stages.

6. A system of claim 1, wherein said hardware monitoring module comprises a function for monitoring execution of operating tests of said primary, intermediate and final stages, said software monitoring module periodically reactivating the function.

7. A system of claim 1, wherein said primary stages of said computing platforms are configured to be used asymmetrically.

8. A system according to claim 7, wherein said primary stage of each said computing platform comprises:
a connector;
an analogue filter module; and
an input signal conversion module,
and wherein using said primary stages of said computing platforms asymmetrically comprises at least one of the following elements:
allocation of different connection points between said connectors;
allocation of different routing paths and/or analogue filters between said analogue filter modules; and
asymmetrical use of said different input signal conversion modules.

9. A system of claim 1, wherein said intermediate stage of each said computing platform comprises a digital acquisition module, the digital acquisition modules of said computing platforms being configured to be used asymmetrically.

10. A system according to claim 9, wherein the use of said digital acquisition modules of said computing platforms in an asymmetrical manner comprises a different sequencing between acquisitions on digital buses and analogue/digital conversions.

11. A system of claim 1, wherein said intermediate stage of each said computing platform comprises a digital processing module configured to encapsulate each digital data item so as to be able to:
use the platform's other modules to check the source of the data;
use the platform's other modules to check the integrity of the data; and
use the platform's other modules to check that the data is dated.

12. A method of verifying the operation of a control system according to claim 1, the method comprising:
injecting predetermined test signals into the primary stage;
acquiring from the final stage of the digital data corresponding to the test signals injected into the primary stage; and
checking that the digital data corresponds to predetermined values.
